(19) United States
(12) Patent Application Publication
(10) Pub. No.: US 2011/0241664 A1
(43) Pub. Date: Oct. 6, 2011

(54) MAGNETIC BIOSENSOR AND A MAGNETIC BIOSENSOR ARRAY COMPRISING THE SAME

(76) Inventor: Biao Zhang, Chicago, IL (US)

(21) Appl. No.: 13/045,083

(22) Filed: Mar. 10, 2011

Related U.S. Application Data
(60) Provisional application No. 61/320,730, filed on Apr. 3, 2010.

(51) Int. Cl. G01R 33/02

(52) U.S. Cl. 324/252; 324/244

(57) ABSTRACT

The magnetic sensor device disclosed herein uses a signal storage magnetic layer for sensing and storing target magnetic field signals. The stored magnetic field signals are then measured by a magnetic sensor.

### CROSS-REFERENCE

This U.S. utility application claims priority from provisional U.S. patent application, “A Magnetic Biosensor and a Magnetic Biosensor Array Comprising the Same,” Ser. No. 61/320,730 to Biao Zhang, confirmation number 5559, filed Apr. 3, 2010. The subject matter of which is incorporated herein by reference in its entirety. The subject matter of co-pending U.S. provisional utility patent application, Ser. No. 61/252,727 filed Oct. 19, 2009 to the same inventor of this provisional application is incorporated herein by reference in its entirety.

### TECHNICAL FIELD OF THE DISCLOSURE

This U.S. patent application relates, in general, to the art of magnetic biosensors, and more particularly, to the art of magnetic biosensor arrays for use in biomolecular related applications.

### BACKGROUND OF THE DISCLOSURE

There exist various magnetic biosensors and magnetic biosensor arrays based on magneto-resistance effect (MR effect), such as spin-valve biosensors, magnetic-tunnel-junction (MTJ) biosensors, and MR biosensors. In biomolecular applications, a magnetic biosensor is used with magnetic nanoparticles (NP) that tag the target biomolecules. By detecting the magnetic field of the NP, existence and the quantity (i.e. the total number) of the NPs are obtained. From the existence and the quantity information, information of the target biomolecules can be extracted. Because the target biomolecules are tagged by the NPs, it is expected that the NPs have an average size matching the characteristic size, such as 20 nm or less of a typical biomolecule, of the target biomolecules.

Some of current magnetic biosensors use NPs of 20 nm or less in size, however, are unable to detect single NP, and thus, can not detect single biomolecule. These biosensors are actually not ready for practical biomolecular applications. Some other current magnetic biosensors use NPs with much larger sizes, such as larger than 150 nm, can detect single NP. However, due to the much larger size compared to the target biomolecules, these biosensors using larger NPs are also not ready for biomolecular applications.

Therefore, what is desired is a magnetic sensor capable of detecting a single NP with a characteristic size matching the size of a typical biomolecule.

### SUMMARY

In one example, a biosensor is disclosed herein. The biosensor comprises: a substrate; a signal storage layer on the substrate for detecting and storing a target magnetic field; and a magnetic sensor positioned between the substrate and the signal storage layer, wherein the magnetic sensor comprises a giant-magneto-resistance element.

In another example, a method of operating a magnetic sensor is disclosed herein, the method comprising: turning off the magnetic sensor; while maintaining the magnetic sensor at the off state, generating a target magnetic field signal; sensing and storing the target magnetic field using a magnetic signal storage layer; and removing the target magnetic field signal; and measuring the stored target magnetic field using a magnetic sensor.

In yet another example, a biochip is disclosed herein, the biochip comprising: an array of magnetic sensors, each magnetic sensor comprises: a substrate; a signal storage layer on the substrate for detecting and storing a target magnetic field; and a magnetic sensor positioned between the substrate and the signal storage layer, wherein the magnetic sensor comprises a giant-magneto-resistance element.

### BRIEF DESCRIPTION OF THE DRAWINGS

Exemplary embodiments of the disclosure will be more clearly understood from the following detailed description taken in conjunction with the accompanying drawings in which:

FIG. 1a diagrammatically illustrates an exemplary magnetic biosensor;

FIG. 1b is a diagram showing the states of the excitation magnetic field, the magnetic sensor, and the storage layer at different operation steps of an exemplary biomolecular application;

FIG. 1c diagrammatically illustrates an exemplary arrangement of heating the signal storage layer of the magnetic sensor in FIG. 1b;

FIG. 1d diagrammatically illustrates another exemplary arrangement of heating the signal storage layer of the magnetic sensor in FIG. 1b;

FIG. 1e diagrammatically illustrates another exemplary arrangement of heating the signal storage layer of the magnetic sensor in FIG. 1b;

FIG. 1f diagrammatically illustrates another exemplary arrangement of heating the signal storage layer of the magnetic sensor in FIG. 1b;

FIG. 2 is a cross-section of an exemplary biosensor comprising a spin-valve and a storage layer;

FIG. 3 is a cross-section of an exemplary biosensor comprising a MTJ and a storage layer;

FIG. 4 is a cross-section of an exemplary biosensor comprising a spin-valve, a MTJ, and a storage layer;

FIG. 5 is a diagram showing an exemplary storage layer of the biosensor in FIG. 1a;

FIG. 6 is a diagram showing another exemplary storage layer of the biosensor in FIG. 1a;

FIG. 7 is a diagram showing yet another exemplary storage layer of the biosensor in FIG. 1a;

FIG. 8 is a diagram showing yet another exemplary storage layer of the biosensor in FIG. 1a;

FIG. 9 is a diagram showing yet another exemplary storage layer of the biosensor in FIG. 1a;

FIG. 10 is a diagram showing the coercivity of a magnetic thin-film varying with temperature;

FIG. 11 is a diagram showing the coercivity of a magnetic thin-film varying with the thickness of the magnetic thin-film;

FIG. 12 is a diagram showing the magnetic exchange energy varying with temperature;

FIG. 13a is a diagram showing yet another exemplary storage layer of the biosensor in FIG. 1a, wherein the storage layer is a magnetic nanowire;

FIG. 13b is a diagram showing the magnetic nanowire in FIG. 13a driven by electrical current; and

FIG. 14 is a diagram of an exemplary magnetic biochip comprising an array of magnetic sensors of FIG. 1a.

### DETAILED DESCRIPTION OF SELECTED EXAMPLES

Hereinafter, selected examples of a magnetic biosensor and a biochip comprising an array of magnetic biosensors will be discussed in the following with reference to the accompanying drawings. It will be appreciated by those skilled in the art that the following discussion is for demonstration purposes, and should not be interpreted as a limitation. Other variances within the scope of this disclosure are also applicable.

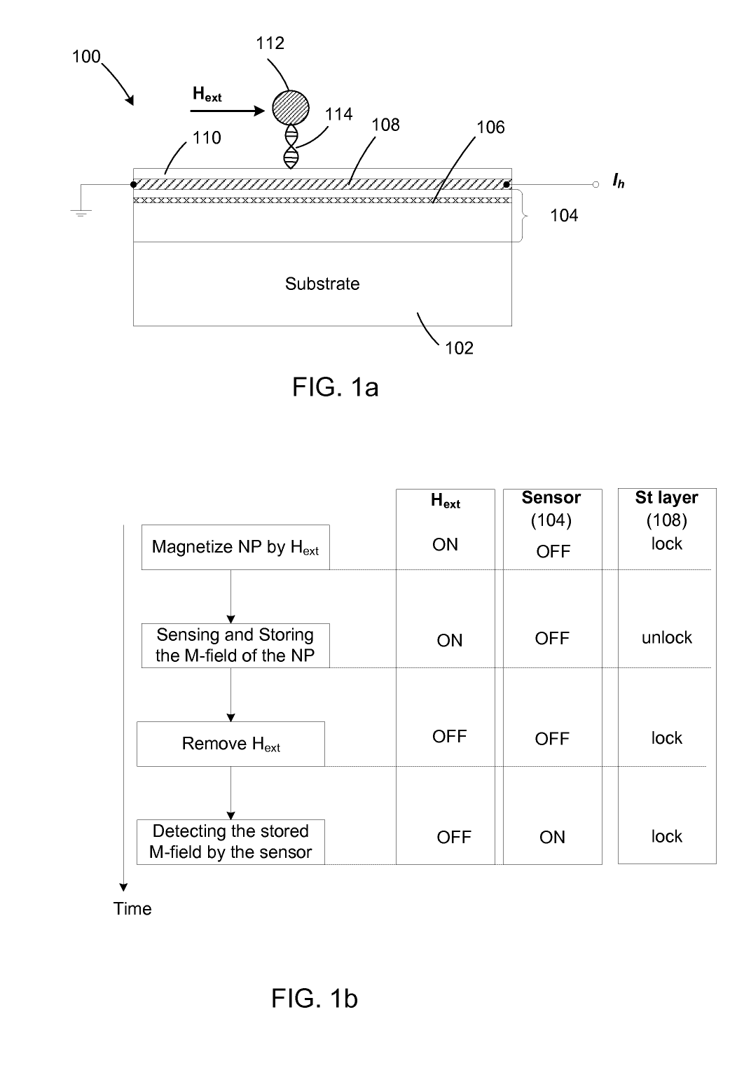

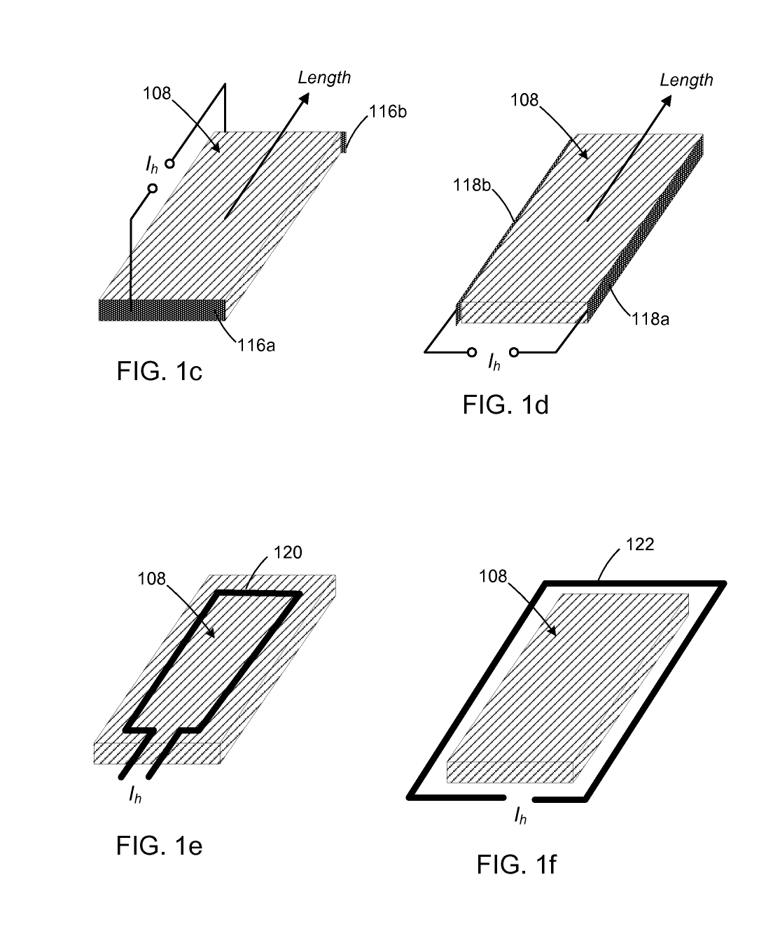

Referring to the drawings, FIG. 1a diagrammatically illustrates a cross-section of an exemplary biosensor. It is noted that other elements, such as mechanism (e.g. a conducting wire) for generating DC or AC in-plane (or vertical) magnetic field, circuits for collecting and processing magnetic-resistance (MR) signals, circuits for operating the individual testing sites, as well as microfluidics devices for delivering nanoparticles to the individual testing sites, are removed from the diagram for simplicity.

As illustrated in FIG. 1a, the biosensor (100) comprises a magnetic sensor (104) (hereafter sensor) formed on a substrate (102), a signal storage layer (108) on the sensor (104), and a coating layer (110). The magnetic sensor (104) can be GMR (giant-magneto-resistance) sensor, such as a spin-valve sensor, a MTJ (magnetic-tunnel-junction) sensor, or other forms of GMR structures. Regardless of different implementations, the GMR sensor (104) comprises a signal sensor layer (106), which is a free magnetic layer (whose magnetic orientation can be aligned according to the target magnetic field to be detected, such as the target magnetic field from the nanoparticle NP 112).

Bio-samples (114) (e.g. hybridized DNA segments attached with a magnetic nanoparticle (112) (hereafter NP) can be immobilized on the surface of the coating layer (110). The excitation magnetic field for magnetize the NP can be applied parallel to (in-plane) or perpendicular (off-plane) to the sensor, by, for example, electrical current above the NP or from under the NP.

The signal-storage layer (108) is provided for sensing the magnetic signal from the NP; and storing the magnetic signal from the NP. In some examples, the signal-storage layer (108) acts as a soft ferromagnetic layer that can also be used for protecting the underneath sensor from being affected by the magnetic field of the above NP. The signal storage layer (108) can be a single magnetic layer comprised of one or more magnetic materials. Alternatively, the signal-storage layer (108) can be a laminate comprised of a stack of multiple layers with at least one layer being comprised of one or more magnetic materials, which will be discussed later. Regardless of the material and structure, the signal-storage layer (108), in some examples, can behave as a hard magnetic layer such that the signal-storage layer (108) has a magnetic blocking temperature above the temperature (e.g. room-temperature RT) of the environment in which the biochip (100) is being operated. For simplicity, the environment temperature is assumed to be the RT (room temperature). However, it is understood by those skilled in the art that the environment temperature may not be the RT in some application. In contrast, the sensor (e.g. the sensor sensing layer SS layer) has a blocking temperature that is equal to or less than the environment temperature (e.g. RT).

Because the signal-storage layer (108) has a blocking temperature higher than the RT, a current is driven through the signal-storage layer during detection to thermally and locally heat the signal-storage layer (108) to an elevated temperature equal to or above its blocking temperature. At the elevated temperature, the signal-storage layer is capable of picking up the target magnetic signal from the NP. After picking up the magnetic signal from the NP, the signal-storage layer is cooled down to the RT. During the cooling process, the magnetic signal picked up from the NP is “frozen” in the signal-storage layer; and the frozen magnetic signal in the signal-storage layer can then be detected by the sensor (104). FIG. 1b diagrammatically illustrates a detection process and the status of the exciting field Hₑₓₜ and the sensor.

Referring to FIG. 1b, the NP is magnetized by the exciting field Hₑₓₜ by turning on the excitation field Hₑₓₜ. The signal-storage layer 108 is locked (i.e. the temperature is below the blocking temperature). The sensor (104) is turned off.

After the magnetization of the NP is stabilized, the magnetic field of the NP is sensed and stored using the signal-storage layer (108). Specifically, the signal-storage layer (108) is heated to an elevated temperature equal to or higher than the blocking temperature by driving a current through the signal-storage layer (unlocking the signal-storage layer). At the elevated temperature, the signal-storage layer detects the fringe magnetic field of the NP. The driving current can be comprised of a sequence of pulses with each pulse having a width (time period) of 1 nanosecond. When the signal-storage layer (108) reaches the expected elevated temperature, the driving current can be removed. The signal-storage layer (108) then picks up the fringe magnetic field; and cools down to the RT. During the cooling down process, the magnetic signal from the NP picked by the signal-storage layer (108) is frozen in the signal-storage layer (108). During this time period, the sensor (104) is kept at the OFF state.

When the signal-storage layer (108) reaches the RT, or after the Signal-storage layer reaches the expected elevated temperature but before turning on the sensor, the excitation field Hₑₓₜ is turned off. At this time, the sensor is OFF, and the Signal-storage layer can be locked (because the Signal-storage layer is at the RT).

After turning off the excitation field, the sensor is turned on to detect the stored magnetic field in the signal-storage layer, wherein the stored magnetic field is correlated to the magnetic field of the NP. During this detection, the sensor is on; and the signal-storage layer is locked (at the RT). The detected magnetic signal can be readout to other functional elements, such as signal processing circuits in the substrate and/or circuits off the substrate.

In general, the signal-storage layer (108) can take any desired geometric shapes, one of which is rectangular as diagrammatically illustrated in FIG. 1c through FIG. 1f. Heating the signal-storage layer (108) can be accomplished by attaching terminals at the major sides and or ends of the signal-storage layer. For example, heating current can be directed through the signal storage layer along the length of the rectangular signal-storage layer (108) via electrical terminals positioned at the opposite ends of the elongated signal storage layer, as illustrated in FIG. 1c.

Alternatively, heating current can be introduced into the signal storage layer (108) along the width (perpendicular to the length) of the signal storage layer by attaching the terminals the opposite ends along the width, as illustrated in FIG. 1d.

In another example, a heating loop (120) can be positioned above or underneath the signal storage layer (108) as illustrated in FIG. 1e. A larger heating loop (122), as illustrated in FIG. 1f, can alternatively be positioned around the signal storage layer (108).

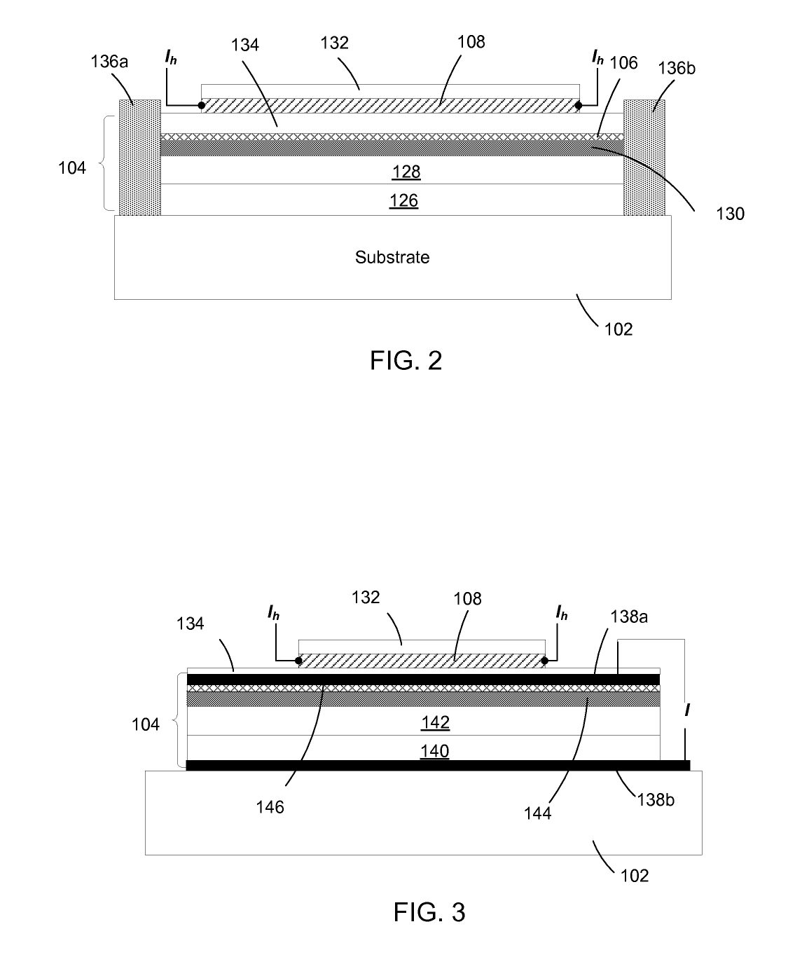

The sensor can be implemented into various configurations, such as a spin-valve, a magnetic-tunnel-junction (MTJ), a MR thin-film device, or any combinations thereof. For demonstration purpose, FIG. 2 diagrammatically illustrates a cross-section of the biosensor in FIG. 1a with the sensor being implemented as a spin-valve.

Referring to FIG. 2, the spin-valve sensor (104) comprises a signal sensing layer (106) for sensing the magnetic field of the signal-storage layer (108); while the signal-storage layer is provided for sensing and storing the magnetic field from the NP (e.g. NP 112 in FIG. 1a). The spin-valve sensor (104) further comprises a n non-magnetic conductive spacer 130 (e.g. Cu), a ferromagnetic layer (128) and a pining layer (126) for aligning the magnetic orientation of ferromagnetic layer 128. The ferromagnetic layer 128 can be a single layer (e.g. CoFe, CoFeB, and other materials). In other examples, the ferromagnetic layer (128) can be a laminate comprised of multiple layers, such as CoFe/Ru/CoFe, CoFeB/Ru/CoFeB, or CoFe/B/Ru/CoFe. The pinning layer (126) can be comprised of PtMn, InMn, or other materials. The pining layer (126) may also be a laminate of multiple layers. Electrical terminals (136a and 136b) are attached to the opposite ends of the sensor (104) for measuring the magnetic-resistance (MR) of the sensor (104). The MR signal can be readout to the following signal processing units to derive the existence and number of the NPs residing at the coating layer (132).

The sensor (104) of FIG. 1a can alternatively be configured in to a MTJ (magnetic tunnel junction), an example of which is diagrammatically illustrated in FIG. 3. Referring to FIG. 3, the biosensor comprises a top and a bottom electrode (138a and 138b). Current is driven through the top and bottom electrodes so as to obtain the MR value of the sensor (104). Because of the top electrode, an insulating layer (134) can be provided between the signal-storage layer (108) and the top electrode (138a) to insulate the signal-storage layer and the top electrode. The MTJ further comprises a free magnetic layer 146 whose magnetic orientation can be aligned according to the target magnetic field to be detected (e.g. the magnetic field from the NP (e.g. NP 112 in FIG. 1a). The free magnetic layer (146) is used herein as a signal sensing layer. Different from the spin-valve configuration, a MTJ uses a dielectric tunnel barrier (144) between free magnetic layer 146 and the pinned ferromagnetic layer 142. The tunnel barrier is a dielectric layer with a typical thickness around or below 1 nm.

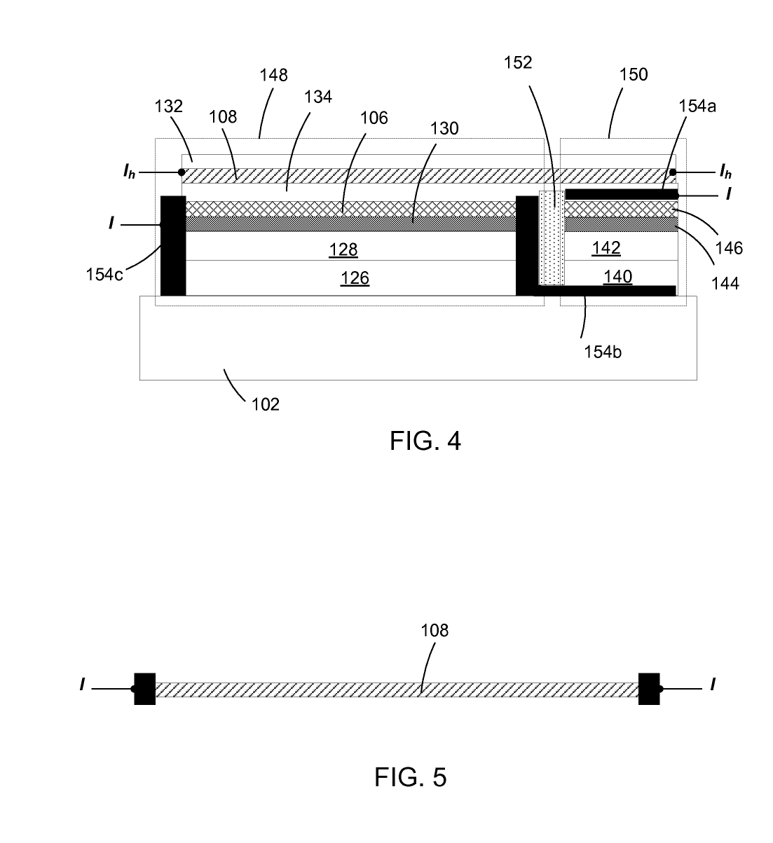

In yet another example, the sensor of FIG. 1a can be implemented as a combination of a spin-valve and a MTJ to improve the MR ratio. FIG. 4 diagrammatically illustrates an example. Referring to FIG. 4, a MTJ sensor and a spin-valve sensor are juxtaposed on a substrate (having formed therein or thereon electrical circuits). The MTJ (150) comprises top electrode 154a, free magnetic layer 146, dielectric tunnel layer 144, pinned ferromagnetic layer 142, pinning layer 140, and electrode 154b. The spin valve (1498) comprises free magnetic layer 106, non-magnetic conductive spacer 130, pinned ferromagnetic layer 128, pinning layer 126, electrodes 154b and 154c. The MTJ (150) and spin-valve (148) can share common layers, such as insulating layer 134, signal-storage layer 108, and coating layer 132 as illustrated in FIG. 4.

The MTJ (150) and spin-valve (148) share a common electrode (154b). Current can be driven from the top electrode (154a) of the MTJ (150) and readout from an electrode 154c of the spin-valve (148). Specifically, current flows through the MTJ from the top electrode (154a) of the MTJ (150), and is collected by the bottom electrode of the MTJ (cross electrode). The cross-electrode feeds the collected current into the spin-valve; and the current flows across the layers of the spin-valve and is collected by the other electrode (electrode 2) of the spin-valve. Because the spin-valve and the MTJ have different spacers (e.g. conductive spacer for spin-valve; and dielectric spacer (e.g. MgO) for the MTJ), the two different spacers are separated by a sensor separator, which can be a thin-layer of insulator/or a barrier. In other examples, the separator may not be provided.

In some examples, the MTJ and the spin-valve sensors can share common functional films, such as ferromagnetic layers, pinning layers, buffer layers, adhesive layers, electrical contact layers, and cap layers, to simplify the design and manufacturing of the sensor. The signal-storage layer (108) preferably has a length that spans across substantially the lengths of the MTJ and the spin-valve.

As mentioned above, the signal-storage layer (108) can be a single ferromagnetic layer, as diagrammatically illustrated in FIG. 4. The signal-storage layer is attached to electrical leads at the ends (or on the top and bottom surfaces) so as to driving current through the signal-storage layer. The material, as well as the geometry (e.g. the thickness) of the signal-storage layer is preferably selected such that at the elevated temperature above the RT, the signal-storage layer is capable of being magnetized by the magnetized NP. FIG. 10 diagrammatically illustrates the temperature dependence of coercivity.

Referring to FIG. 10, the coercivity decreases with increased temperature. At RT, the signal-storage layer has a coercivity that is higher than the magnetic H_{NP} from of the NP at the signal-storage layer. As the temperature of the signal-storage layer increases, the coercivity of the signal-storage layer decreases. At the storing temperature (or the blocking temperature wherein the signal storage layer transits from ferromagnetic to paramagnetic or super-paramagnetic), the coercivity of the signal-storage layer is equal to or less than H_{NP} such that the signal-storage layer is capable of picking up the magnetic signal from the NP (i.e. from being magnetized by the NP). After the magnetization, the signal-storage layer drops its temperature from the elevated temperature (storing temperature) to the RT. During this cooling process, the magnetic signal picked up from the NP is “frozen” in the signal-storage layer as a stored magnetic signal in the signal-storage layer. The stored magnetic field can then be measured by a magnetic sensor, such as a spin-valve, a MTJ, a MR device, or other magnetic detection devices.

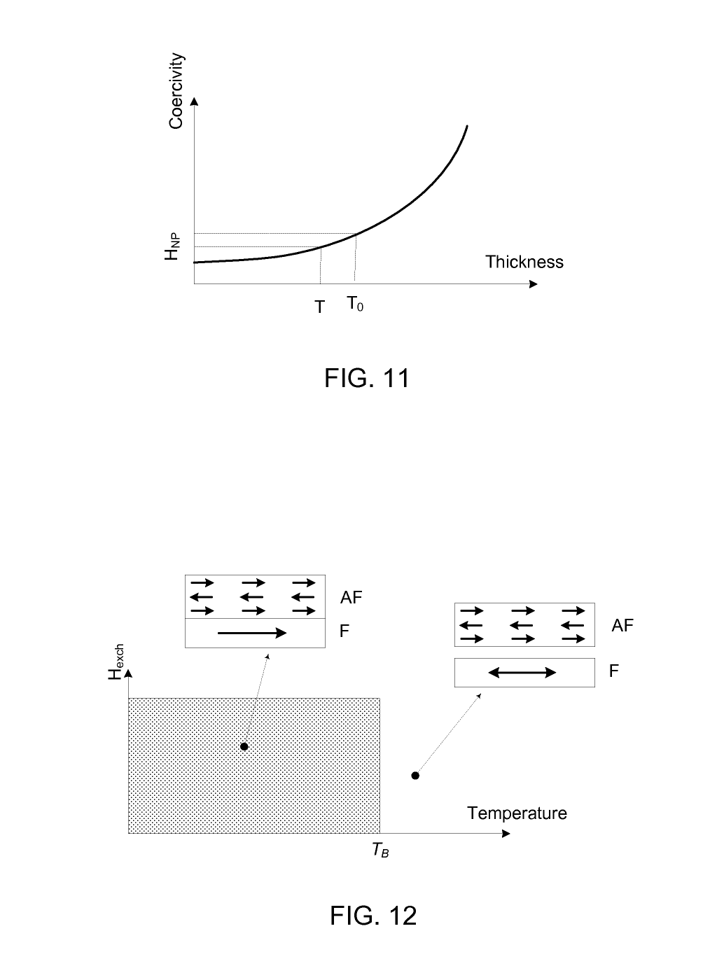

The coercivity of a magnetic thin-film (layer) also varies with its thickness, as diagrammatically illustrated in FIG. 11. The signal-storage layer can have a thickness such that the coercivity of the signal-storage layer is in the vicinity of the H_{NP}, such as within a range of ±0.5%, ±1%, ±1.5%, ±2%, ±2.5%, ±3%, ±4%, ±5%, ±8%, ±10% of H_{NP}. Especially when the Signal-storage layer has a thickness such that its coercivity is higher than H_{NP}, a thermal layer can be provided to adjust the coercivity of the Signal-storage layer.

As mentioned above, the NP can be magnetized at any desired time after it is positioned at the testing site, but preferably before activating the magnetic sensor that is used for detecting the stored magnetic field in the signal-storage layer. The signal-storage layer can be heated to the elevated temperature at any time; while it is preferred that the signal-storage layer is cooled down after the magnetization of the NP but before activating the magnetic sensor for detecting the magnetic signal stored in the signal-storage layer.

The signal-storage layer can be implemented into many forms. In one example as illustrated in FIG. 5, the signal storage layer 108 can be implemented as a single ferromagnetic layer having a blocking temperature higher than the temperature at which the bio-sensor (comprising the signal storage layer) is to be operated.

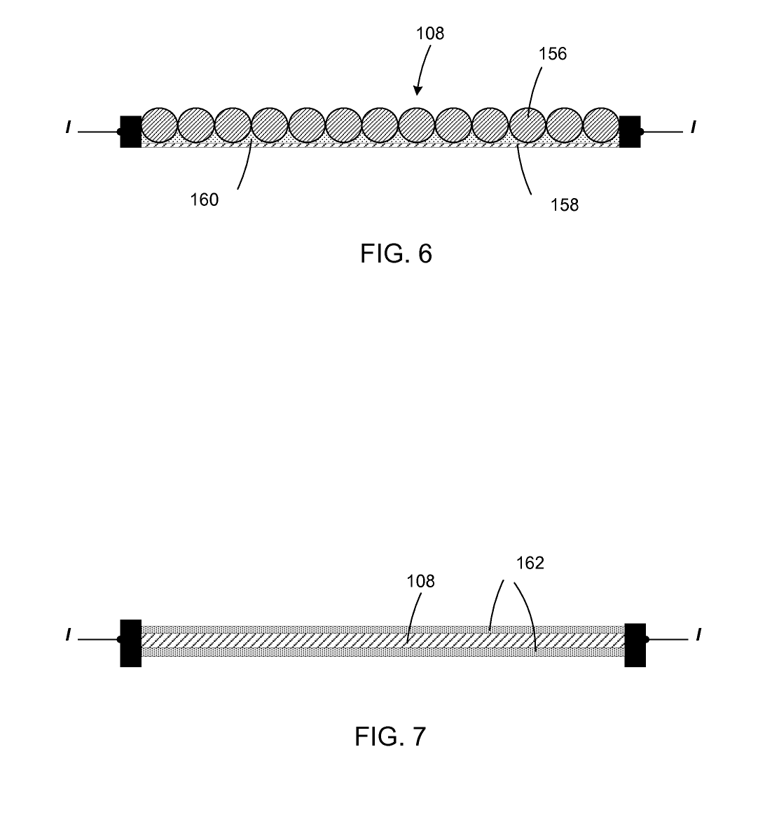

As another example, the signal-storage layer can be implemented as a combination layer comprising an attaching layer and a filling layer, as diagrammatically illustrated in FIG. 6.

Referring to FIG. 6, the signal-storage layer (108) comprises a filling layer (156), wherein the filling layer is comprised of a magnetic material, preferably a superparamagnetic material. In one example, the filling layer is comprised of superparamagnetic particles (islands, clusters, balls, etc). In one example, the superparamagnetic particles can be magnetic nanoparticles (balls), and the nanoparticles have an average diameter of 50 nm or less, preferably 20 nm or less. The nanoparticles are preferably attached to and thus, supported by an attaching layer (158). In particular, the attaching layer can be a PEI (poly ethylenimine) layer, on which magnetic nanoparticles can self-assembling into a substantially monolayer. The filling layer may further comprise other materials, such as an electrically conductive material 160 (e.g. organic, inorganic, polymer) to enhance the electrical conductivity of the Signal-storage layer and/or to enhance the adhesion of the nanoparticles therebetween. The electrical terminals (leads) can be attached to the ends or the top and bottom surface of the signal-storage layer.

In order to improve the heating efficiency and secure the local heating, a thermal layer e.g. a layer with a low thermal conductivity, can be provided, as diagrammatically illustrated in FIG. 7. Referring to FIG. 7, a thermal layer (162) can be positioned at the top surface, and/or the bottom surface of the signal-storage layer (108). The thermal layer can be electrically conductive or can be electrically insulating. An exemplary thermal thin-film layer can be a GeTeSb layer, or a laminate of a GeTeSb layer and one or more (e.g. at the top and bottom surfaces of the GeTeSb layer) TiWN₂ layer.

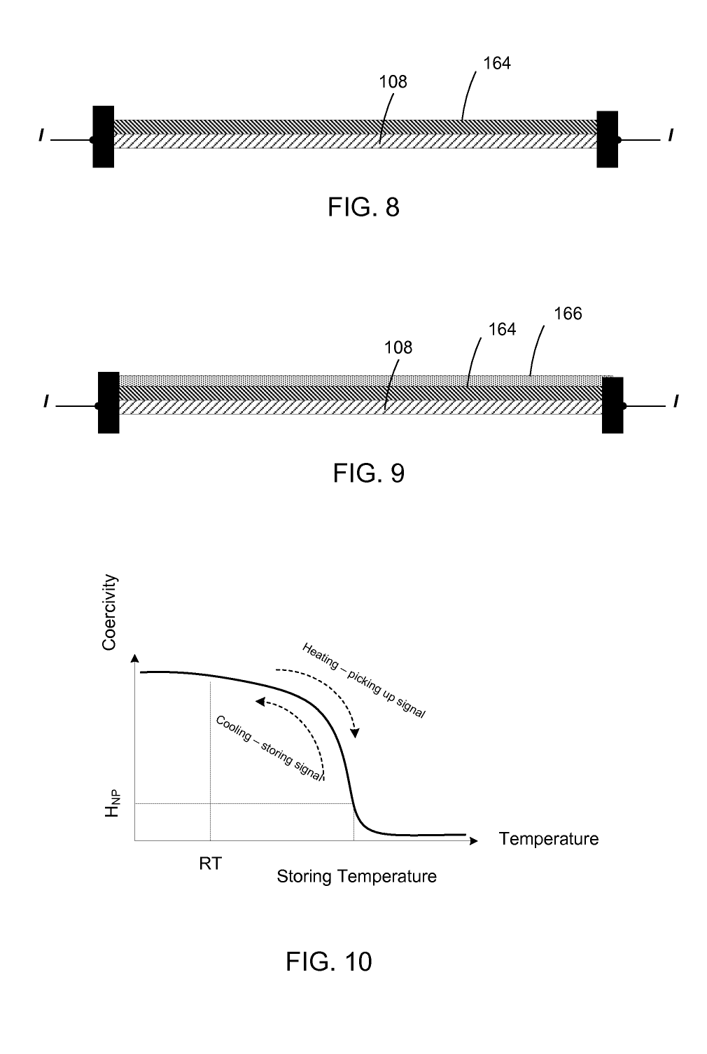

In yet another example, the signal-storage layer can be comprised of a ferromagnetic material; and laminated with an antiferromagnetic layer to form a magnetic-pining structure, as diagrammatically illustrated in FIG. 8. Referring to FIG. 8, the signal-storage layer (108) is comprised of a ferromagnetic material, thus behaves ferromagnetic. The pin layer (164) is comprised of an antiferromagnetic material and thus behaves antiferromagnetic. By laminating the signal-storage layer (108) and the pin layer (164), the magnetic orientation of the ferromagnetic signal-storage layer can be pinned by the antiferromagnetic pin layer through magnetic exchange energy at the operating temperature (e.g. RT). When the laminate of the signal-storage layer and the pin layer is heated to an elevated temperature, the pin layer and the signal-storage layer is magnetically decoupled, as diagrammatically illustrated in FIG. 12. As shown in FIG. 12, the antiferromagnetic (AF) pin layer is magnetically decoupled with the ferromagnetic (F) signal-storage layer at the elevated temperature. As a consequence, the unpinned (unlocked) ferromagnetic signal-storage layer can be magnetized by the magnetic field from the magnetized nanoparticle (NP). In this instance, it is preferred that the signal-storage layer is comprised of a soft magnetic material.

Alternatively, the signal-storage layer can be comprised of a hard magnetic material. In this example, a thermal layer can be provided to heat the signal-storage layer to an elevated temperature in the same way as discussed above. An exemplary signal-storage layer with a pin layer and a heat layer is diagrammatically illustrated in FIG. 9. In this example, element 108 is a signal storage layer; element 164 is a heating layer; and element 166 is a pinning layer. It is noted that the pinning layer 166 can be positioned between the signal storage layer 108 and the heating layer 164.

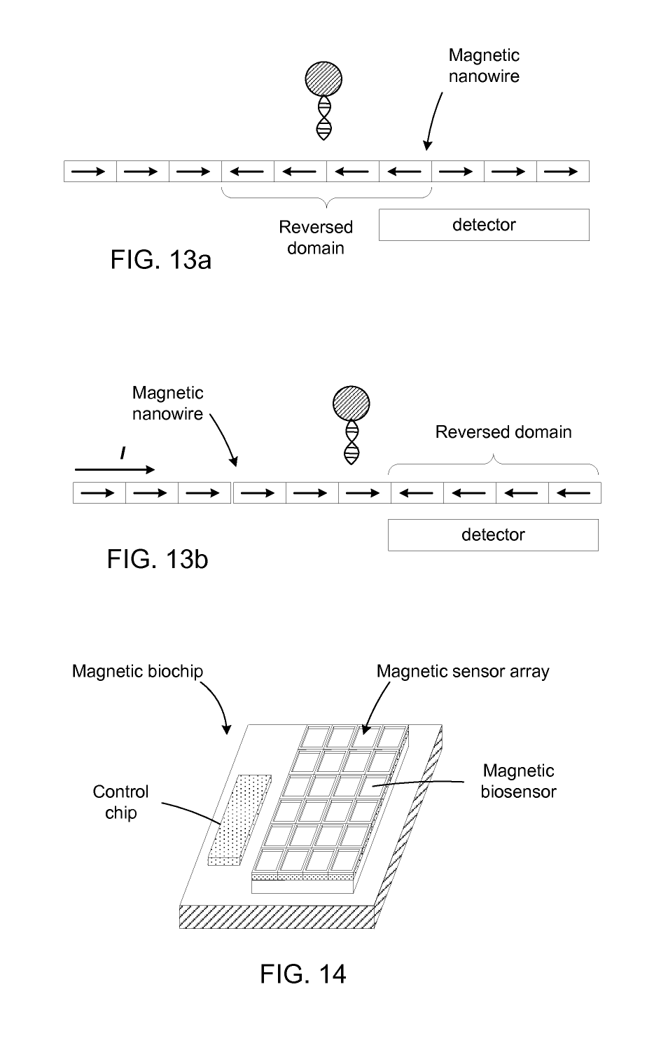

As yet another example, the signal-storage layer can be implemented according to another magnetic-signal storing mechanism, as diagrammatically illustrated in FIG. 13a and FIG. 13b. Referring to FIG. 13a, the Signal-storage layer can be formed as a magnetic nanowire with a characteristic diameter of 50 nanometers or less, such as 30 nanometers or less. The magnetic nanowire (nanowire) comprises a series of magnetic domains separated by domain walls.

The nanowire is positioned above a magnetic detector (e.g. a spin-valve, a MTJ, a MR sensor, or other type of magnetic sensors); while the detector is aligned to only a portion of the nanowire. For example, the length of the detector is around the total length of several (e.g. 30 or less, 20 or less, 15 or less, 6 or less, 5 or less, but longer than 1 or 2 magnetic domains) magnetic domains. The nanowire can have a length of 5 nanometers or longer, such as 10 nanometers or longer, 15 nanometers or longer, 20 nanometers or longer, but preferably less than 100 nanometers.

The magnetic nanoparticle is positioned above the nanowire. After being magnetized, the magnetic nanoparticle magnetizes (e.g. changes the magnetic states) a number of magnetic domains in the magnetic nanowire. By driving an electrical current through the nanowire, as diagrammatically illustrated in FIG. 13b, the magnetic domains moves from one end towards the other. As the magnetized (changed magnetic states) domain by the NP moves across the above area of the detector, the detector detects the magnetization or the change of the magnetic states of the magnetic domain. According to the detected signal, the magnetic field from the NP can thus be obtained.

The biosensors as discussed above, as well as those variations within the scope of this disclosure, can be used in a biosensor array, an example of which is diagrammatically illustrated in FIG. 14. Referring to FIG. 14, magnetic biochip comprises a magnetic sensor array and a control chip. The magnetic sensor array comprises magnetic bio sensors organized in an array. The magnetic sensor array may have any desired number of biosensors; and with any desired aspect ratios (the number of biosensors in a row vs. the number of biosensors in a column). The control chip can be an IC chip for controlling operation of the magnetic sensor array, as well as providing services for data management.

It will be appreciated by those skilled in the art that the above discussion is for demonstration purpose; and the examples discussed above are some of many possible examples. Other variations are also applicable.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments. Furthermore, for ease of understanding, certain method procedures may have been delineated as separate procedures; however, these separately delineated procedures should not be construed as necessarily order dependent in their performance. That is, some procedures may be able to be performed in an alternative ordering, simultaneously, etc. In addition, exemplary diagrams illustrate various methods in accordance with embodiments of the present disclosure. Such exemplary method embodiments are described herein using and can be applied to corresponding apparatus embodiments, however, the method embodiments are not intended to be limited thereby.

Although few embodiments of the present invention have been illustrated and described, it would be appreciated by those skilled in the art that changes may be made in these embodiments without departing from the principles and spirit of the invention. The foregoing embodiments are therefore to be considered in all respects illustrative rather than limiting on the invention described herein. Scope of the invention is thus indicated by the appended claims rather than by the foregoing description, and all changes which come within the meaning and range of equivalency of the claims are intended to be embraced therein. As used in this disclosure, the term “preferably” is non-exclusive and means “preferably, but not limited to.” Terms in the claims should be given their broadest interpretation consistent with the general inventive concept as set forth in this description. For example, the terms “coupled” and “connect” (and derivations thereof) are used to connote both direct and indirect connections/couplings. As another example, “having” and “including”, derivatives thereof and similar transitional terms or phrases are used synonymously with “comprising” (i.e., all are considered “open ended” terms)—only the phrases “consisting of” and “consisting essentially of” should be considered as “close ended”. Claims are not intended to be interpreted under 112 sixth paragraph unless the phrase “means for” and an associated function appear in a claim and the claim fails to recite sufficient structure to perform such function.

I claim:

1. A biosensor, comprising:
a substrate;
a signal storage layer on the substrate for detecting and storing a target magnetic field; and
a magnetic sensor positioned between the substrate and the signal storage layer, wherein the magnetic sensor comprises a giant-magneto-resistance element.

2. The biosensor of claim 1, wherein the magnetic sensor comprises a magnetic tunnel junction.

3. The biosensor of claim 1, wherein the magnetic sensor comprises a spin-valve structure.

4. The biosensor of claim 1, further comprises a coating layer fir immobilizing a molecule.

5. The biosensor of claim 1, wherein the signal storage layer has a blocking temperature equal to or higher than an operating temperature at which the biosensor is being operated.

6. The biosensor of claim 5, wherein the signal storage layer is electrically connected to a current source for elevating the temperature of the signal storage layer.

7. The biosensor of claim 1, wherein the signal storage layer comprises a ferromagnetic layer and a pinning layer that is magnetically coupled with the ferromagnetic layer for pinning the magnetic orientation of the ferromagnetic layer such that: 1) the magnetic orientation is substantially unchangeable at the operating temperature at which the biosensor is being operated; and 2) the magnetic orientation is aligned to a target magnetic field as a consequence of decoupling of the ferromagnetic layer and the pinning layer at a higher temperature than the operating temperature.

8. A method of operating a magnetic sensor, the method comprising:
turning off the magnetic sensor;
while maintaining the magnetic sensor at the off state,
generating a target magnetic field signal;
sensing and storing the target magnetic field using a magnetic signal storage layer; and
removing the target magnetic field signal; and
measuring the stored target magnetic field using a magnetic sensor.

9. The method of claim 8, wherein the step of generating the target magnetic field signal comprises:
applying an external magnetic field to magnetize a magnetic nanoparticle, and wherein the target magnetic field signal is generated by the magnetized nanoparticle.

10. The method of claim 9, wherein the step of sensing and storing the target magnetic field comprises:
heating the signal storage layer to an elevated temperature equal to or above the blocking temperature of the signal storage layer;
sensing and storing the target magnetic field; and
cooling down the signal storage layer from the elevated temperature to an operating temperature at which the sensor is being operated.

11. The method of claim 9, wherein the signal storage layer comprises a ferromagnetic layer and a pining layer that is magnetically coupled to the ferromagnetic layer for pining the magnetic orientation of the ferromagnetic layer, wherein the step of sensing and storing the target magnetic field comprises:
heating the signal storage layer to an elevated temperature so as to decouple the ferromagnetic layer and the pining layer;
sensing and storing the target magnetic field; and
cooling down the signal storage layer from the elevated temperature to or below a temperature at which the ferromagnetic layer and the pining layer is magnetically coupled.

12. A biochip, comprising:
an array of magnetic sensors, each magnetic sensor comprises:
a substrate;
a signal storage layer on the substrate for detecting and storing a target magnetic field; and
a magnetic sensor positioned between the substrate and the signal storage layer, wherein the magnetic sensor comprises a giant-magneto-resistance element.

13. The biochip of claim 12, wherein the magnetic sensor comprises a magnetic tunnel junction.

14. The biochip of claim 12, wherein the magnetic sensor comprises a spin-valve structure.

15. The biochip of claim 12, wherein the signal storage layer has a blocking temperature equal to or higher than an operating temperature at which the biosensor is being operated.

16. The biosensor of claim 15, wherein the signal storage layer is electrically connected to a current source for elevating the temperature of the signal storage layer.

17. The biosensor of claim 12, wherein the signal storage layer comprises a ferromagnetic layer and a pinning layer that is magnetically coupled with the ferromagnetic layer for pinning the magnetic orientation of the ferromagnetic layer such that: 1) the magnetic orientation is substantially unchangeable at the operating temperature at which the biosensor is being operated; and 2) the magnetic orientation is aligned to a target magnetic field as a consequence of decoupling of the ferromagnetic layer and the pinning layer at a higher temperature than the operating temperature.
